(19) United States
(12) Patent Application Publication
(10) Pub. No.: US 2007/0015369 A1
(43) Pub. Date: Jan. 18, 2007

(54) Method of manufacturing a semiconductor device

(76) Inventor: Akihiro Takase, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/447,877

(22) Filed: Jun. 7, 2006

(30) Foreign Application Priority Data
Jun. 16, 2005 (JP) 2005-176582

(51) Int. Cl. H01L 21/461; H01L 21/302

(52) U.S. Cl. 438/706

(57) ABSTRACT

A method of manufacturing a semiconductor device, includes forming a lower organic insulating film, inorganic insulating film and upper organic insulating film, making a first hole which has first and second parts passing through the upper organic insulating film and the inorganic insulating film, and performing dry etching on the upper organic insulating film and that part of the lower organic insulating film which lies below the first hole, by using etching gas containing at least one of oxygen gas and nitrogen gas, thereby making a second hole having the second part and a third part which passes through the lower organic insulating film, and thereby removing the upper organic insulating film, wherein performing the dry etching includes removing at least a part of the upper organic insulating film in a condition that residence time of the etching gas is 0.25 second or more in a chamber.

### CROSS-REFERENCE TO RELATED APPLICATIONS

This application is based upon and claims the benefit of priority from prior Japanese Patent Application No. 2005-176582, filed Jun. 16, 2005, the entire contents of which are incorporated herein by reference.

### BACKGROUND OF THE INVENTION

1. Field of the Invention

The present invention relates to a method of manufacturing a semiconductor device.

2. Description of the Related Art

In recent years, holes are made in a stack film formed of organic and inorganic insulating films and used as an interlayer insulating film, in some methods of manufacturing semiconductor devices. (See, for example, Jpn. Pat. Appln. KOKAI Publication No. 2003-45964.)

Assume that a lower organic insulating film, an inorganic insulating film and an upper organic insulating film are formed, one on another, on an underlying region, and holes are made in the inorganic insulating film and the lower organic insulating film, using the upper organic insulating film as mask. In this case, it is hard to control the selective ratio of etching between the upper organic insulating film and the lower organic insulating film. Consequently, the lower organic insulating film is over-etched excessively, rendering it difficult to make holes of a desired shape.

It is hard to control the etching rate in the process of making holes in the stack film formed of the organic insulating film and the inorganic insulating film. Consequently, a desirable hole pattern of a desired shape cannot be reliably formed.

### BRIEF SUMMARY OF THE INVENTION

An aspect of the present invention, there is provide a method of manufacturing a semiconductor device, comprising: forming a lower organic insulating film on an underlying region; forming an inorganic insulating film on the lower organic insulating film; forming an upper organic insulating film on the inorganic insulating film; making a first hole which has first and second parts passing through the upper organic insulating film and the inorganic insulating film, respectively; and performing dry etching on the upper organic insulating film and that part of the lower organic insulating film which lies below the first hole, by using etching gas containing at least one of oxygen gas and nitrogen gas, thereby making a second hole having the second part and a third part which passes through the lower organic insulating film, and thereby removing the upper organic insulating film, wherein performing the dry etching includes removing at least a part of the upper organic insulating film in a condition that residence time of the etching gas is 0.25 second or more in a chamber in which the dry etching is performed.

### BRIEF DESCRIPTION OF THE SEVERAL VIEWS OF THE DRAWINGS

FIGS. 1 to 5 are sectional views, schematically illustrating a method of manufacturing a semiconductor device, according to an embodiment of this invention;

FIG. 6 is a diagram representing the relation between the residence time, etching rate and selective ratio of etching; and

FIG. 7 is a diagram representing the relation between the etching time and the etching amount.

### DETAILED DESCRIPTION OF THE INVENTION

An embodiment of this invention will be described, with reference to the accompanying drawings.

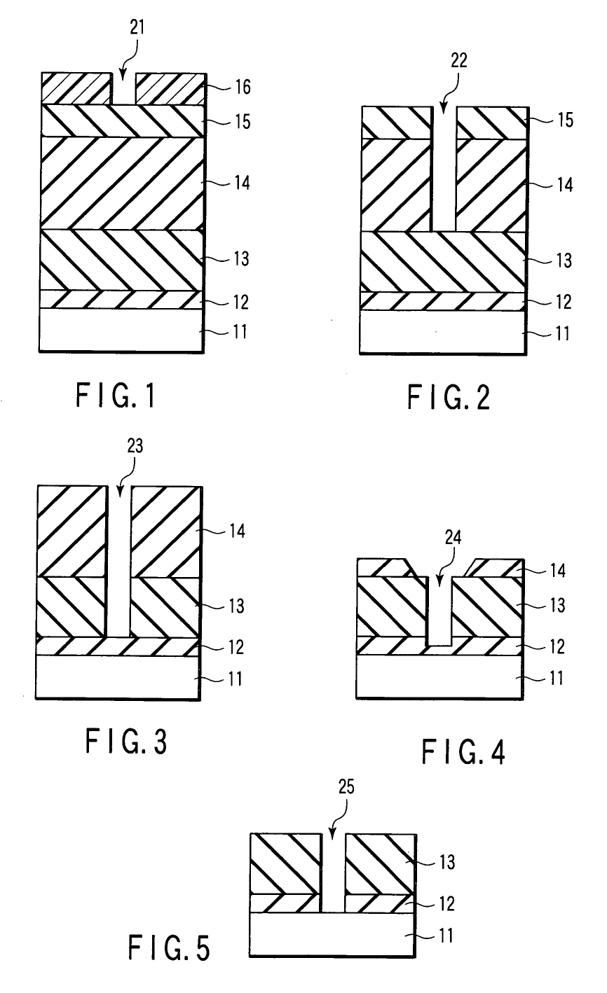

FIGS. 1 to 5 are sectional views that schematically illustrate a method of manufacturing a semiconductor device, according to an embodiment of this invention;

A semiconductor substrate with an underlying region 11 having a desired structure is prepared. As shown in FIG. 1, a lower organic insulating film 12 about 80 nm thick is formed on the underlying region 11 by means of coating. A silicon oxide (SiO₂) film about 260 nm thick is formed, as inorganic insulating film 13, on the lower organic insulating film 12 by performing chemical vapor deposition (CVD). An upper organic insulating film 14 about 300 nm thick is formed on the inorganic insulating film 13 by means of coating. Further, a spin-on-glass (SOG) film 15 about 110 nm thick is formed on the upper organic insulating film 14. Still further, a resist pattern 16 having a hole pattern 21 is formed on the SOG film 15 by means of photolithography. The resist pattern 16 is made of, for example, photoresist that is sensitive to ArF light (wavelength: 193 nm).

Subsequently, dry etching is performed on the SOG film 15, using the resist pattern 16 as mask, as illustrated in FIG. 2. Using the SOG film 15 thus etched as mask, dry etching is performed on the upper organic insulating film 14. As a result, a hole 22 is made in the SOG film 15 and the upper organic insulating film 14. The hole 22 extends downwards, reaching the surface of the inorganic insulating film 13.

Next, dry etching is carried out on the inorganic insulating film 13 as illustrated in FIG. 3. In this dry etching, the SOG film 15 and upper organic insulating film 14, which have the hole 22, is used as mask. As the etching proceeds, the SOG film 15 ceases to exist. Thereafter, the upper organic insulating film 14 serves as etching mask. During this etching, a hole (first hole) 23 is made in the upper organic insulating film 14 and the inorganic insulating film 13, reaching the surface of the lower organic insulating film 12. The hole 23 has a first part passing through the upper organic insulating film 14 and a second part passing through the inorganic insulating film 13. During the etching, the upper part of the upper organic insulating film 14 is etched away, reducing the thickness of the upper organic insulating film 14 to about 250 nm. The hole 23 made at this time has a diameter of about 90 nm.

As shown in FIGS. 4 and 5, dry etching is performed on the lower organic insulating film 12 below the hole 23, using, as mask, the upper organic insulating film 14 and the inorganic insulating film 13 having the hole 23. As a result, a hole (second hole) 25 is made in the inorganic insulating film 13 and lower organic insulating film 12, reaching the surface of the underlying region 11. The hole 25 has a second part passing through the inorganic insulating film 13 and a third part passing through the lower organic insulating film 12. During the dry etching, the upper organic insulating film 14 is removed. The etching gas used is a mixture of oxygen gas (O₂) and nitrogen gas (N₂). The hole 25 will be filled with conductive material such as metal (not shown). The etching step, which has been explained with reference to FIGS. 4 and 5, will be described in detail.

The upper organic insulating film 14, used as mask for making the hole 25 in the etching explained with reference to FIGS. 1 to 5, is usually thicker than the lower organic insulating film 12 that is used as an interlayer insulating film. When the step of FIG. 3 is completed, the lower organic insulating film 12 and the upper organic insulating film 14 are about 80 nm and about 250 nm thick, respectively, as indicated above. Thus, the upper organic insulating film 14 is thicker than the lower organic insulating film 12.

In most cases, the upper organic insulating film 14 is formed of an ordinary organic insulating film containing carbon as a main component. By contrast, the lower organic insulating film 12 is formed of an organic insulating film having a relative dielectric constant of about 3.3 or less. To have a smaller relative dielectric constant, the lower organic insulating film 12 may be a porous one having a lower density. Hence, in most cases, the lower organic insulating film 12 has a smaller relative dielectric constant than the upper organic insulating film 14. Further, the lower organic insulating film 12 has a lower density than the upper organic insulating film 14.

In a normal condition, a first organic insulating film used for the lower organic insulating film 12 has a higher etching rate than a second organic insulating film used for the upper organic insulating film 14, with respect to the etching gas that is used in the step of FIGS. 4 and 5. More specifically, if the first and second organic insulating films are formed on flat surfaces, the first organic insulating film has a higher etching rate than the second organic insulating film. If the lower organic insulating film 12 is a porous film having a lower density, it will have an even higher etching rate than the upper organic insulating film 14.

Hence, if the etching of FIGS. 4 and 5 is carried out under normal conditions, the underlying region 11 will be exposed well before the upper organic insulating film 14 is completely removed. After the underlying region 11 is exposed, the lower organic insulating film 12 is over-etched excessively. Consequently, the side etching proceeds on the lower organic insulating film 12, making it difficult for the hole 25 to be vertical as is desired.

In the present embodiment, the above-mentioned dry etching is performed under such a condition that the etching gas has a residence time of 0.25 sec or more in the etching chamber. The residence time is proportional to the volume of the chamber and the pressure in the chamber and is inversely proportional to the flow rate of the etching gas. The residence time T (seconds) can be given as follows:
T=(V×P)/(1.27×10⁻²×F) (1)

where V (liters) is the volume of the chamber, P (Torr) is the pressure in the chamber, and F (sccm) is the flow rate of the etching gas. Volume V of the chamber is known. Pressure P in the chamber and flow rate F of the etching gas can easily be measured by manometer and flow meter. Residence time T can therefore be calculated from the equation (1).

As described above, the dry etching is performed under such a condition that the etching gas has a residence time of 0.25 sec or more. Namely, the residence time is longer than in the ordinary dry etching. This prevents the above-mentioned problem from arising.

The longer the residence time, the longer the gas will stay in the chamber. Accordingly, the gas will stay longer in the holes 23 and 24 shown in FIGS. 3 and 4. Therefore, it is difficult to supply the etching gas into the holes 23 and 24 and to expel, from the holes 23 and 24, the gas generated during the etching. As a result, the lower organic insulating film 12 is hardly etched. That is, the etching rate of the lower organic insulating film 12 can be greatly lowered. Thus, the upper organic insulting film 14 can be etched at a rate much higher than the lower organic insulating film 12 in the process of FIGS. 3 to 5. The upper organic insulating film 14 can therefore be entirely and completely removed before the underlying region 11 is exposed. This prevents the lower organic insulating film 12 from being excessively over-etched, and the hole 25 can be vertical as desired. In other words, the entire side surface of the hole 25 can be substantially vertical as illustrated in FIG. 5.

When the dry etching of the lower organic insulating film 12 is continued until the surface of the underlying region 11 is exposed after the upper organic insulating film 14 is removed in whole, the residence time of the etching gas is not necessarily be 0.25 sec or more. If the upper organic insulating film 14 is dry-etched until it becomes sufficiently thin, with the residence time of the etching gas maintained at 0.25 sec or more, the subsequent dry etching need not be performed such that the etching gas has a residence time of 0.25 sec or more. In other words, the residence time of the etching gas need not be 0.25 sec or more all the time the upper organic insulating film 14 is being etched.

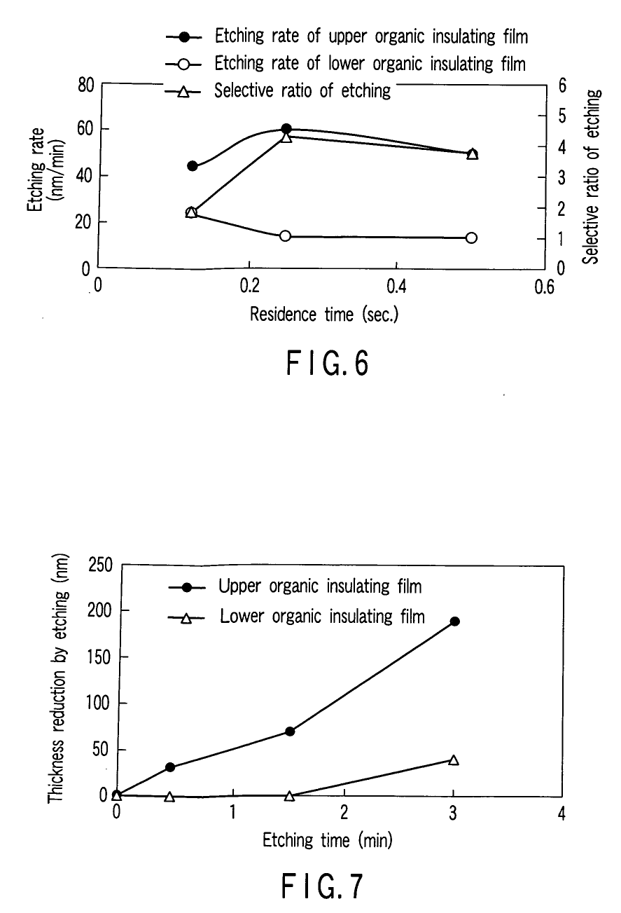

FIG. 6 is a diagram representing the relation between the residence time, the etching rates of the lower and upper organic insulating films 12 and 14, and the selective ratio of etching (i.e. ratio of the etching rate of the film 14 to that of the film 12). This relation is based on three samples of the structure of FIG. 3. In each sample, the lower organic insulating film 12 is made of SiLK (manufactured by Dow Chemical Company) and about 80 nm thick, the upper organic insulating film 14 is formed of coating type carbon film and about 250 nm thick, the inorganic insulating film 13 is about 260 nm thick, and the hole 23 has a diameter of about 90 nm. The dimensions specified here are normal and typical values. Note that a residence time of 0.125 sec is set for the first sample, a residence time of 0.25 sec for the second sample, and a residence time of 0.5 sec for the third sample.

The three samples were made, setting the pressure in the chamber to 50 mTorr, supplying high-frequency power of 300 W to the chamber electrodes, and setting the etching time to 3 minutes. For the first sample (residence time: 0.125 sec), O₂ and N₂ were applied at 20 sccm and 400 sccm, respectively. For the second sample (residence time: 0.25 sec), O₂ and N₂ were applied at 10 sccm and 200 sccm, respectively. For the third sample (residence time: 0.5 sec), O₂ and N₂ were applied at 5 sccm and 100 sccm, respectively. That is, the flow rates of the etching gases were changed to vary the residence time. At the completion of the 3-minute drying etching, the samples acquired the structure of FIG. 4, not the finished structure of FIG. 5.

After performing the dry etching for 3 minutes, the samples were examined for thickness reduction (etching amount), average etching rate and selective ratio of etching. The results were as follows:
(1) First sample (residence time: 0.125 sec)

Thickness reduction of film 14: 133 nm

Average etching rate of film 14: 44.3 nm/min

Thickness reduction of film 12: 72 nm

Average etching rate of film 12: 24 nm/min

Selective ratio of etching: 1.85
(2) Second sample (residence time: 0.25 sec)

Thickness reduction of film 14: 180 nm

Average etching rate of film 14: 60 nm/min

Thickness reduction of film 12: 42 nm

Average etching rate of film 12: 14 nm/min

Selective ratio of etching: 4.29
(3) Third sample (residence time: 0.5 sec)

Thickness reduction of film 14: 151 nm

Average etching rate of film 14: 50.3 nm/min

Thickness reduction of film 12: 40 nm

Average etching rate of film 12: 13.3 nm/min

Selective ratio of etching: 3.78

The results set forth above are illustrated in FIG. 6. As seen from FIG. 6, the selective ratio of etching is 1.85 for the first sample in which the residence time is set at 0.125 sec. By contrast, the selective ratios of etching for the second and third samples in which the residence time is set at 0.25 sec and 0.5 sec are 4.29 and 3.78, respectively. Obviously, the selective ratio of etching (i.e., ratio of the etching rate of the film 14 to that of the film 12) is increased greatly. Thus, a high selective ratio of etching can be attained by setting the residence time at 0.25 sec or more. As a result, the upper organic insulating film 14 can therefore be completely and entirely removed before the surface of the underlying region 11 is exposed through the hole made in the lower organic insulating film 12. Hence, the hole 25 having a desired vertical shape can be formed without over-etching the lower organic insulating film 12 excessively.

FIG. 7 represents the relation between the etching time and the thickness reductions by etching (i.e., thickness reductions of the lower and upper organic insulating films 12 and 14), which is observed in the second sample (residence time: 0.25 sec).

As can be understood from FIG. 7, the lower organic insulating film 12 was scarcely etched upon lapse of about 1.5 minutes from the start of etching. The film 12 was etched, becoming thinner by about 40 nm, upon lapse of 3 minutes from the start of etching. This is probably because the upper organic insulating film 14 remained so thick that the etching gas could hardly be supplied and the gas generated by etching could hardly be expelled. Thus, FIG. 7 shows that the upper organic insulating film 14 can be etched a much higher rate than the lower organic insulating film 12 until about 3 minutes elapses from the start of etching.

As described above, the sample has such a shape as shown in FIG. 4 at the time the etching has proceed for 3 minutes. Since the inorganic insulating film 13 is about 260 nm thick, the thickness reduction of the lower organic insulating film 12 is about 40 nm and the hole 24 (made in the films 13 and 12) has a diameter of about 90 nm, the hole 24 has an aspect ratio of about 3(=(260+40)/90) at the time the etching has proceeded for 3 minutes. Even if the aspect ratio is about 3, a sufficient selective ratio of etching can be attained by setting the residence time to 0.25 seconds or more. As can be clear from the above, the higher the aspect ratio, the more the selective ratio of etching will increase. Thus, in a case where a hole having an aspect ratio of 3 or more is formed, the etching can be performed at a sufficient selective ratio of etching by setting the residence time to 0.25 sec or more.

In the present embodiment, dry etching is performed in such a condition that the residence time of the etching gas in the chamber is 0.25 sec or more. The upper organic insulating film 14 can therefore be etched at a higher rate than the lower organic insulating film 12. Hence, a hole 25 that is vertical as desired can be made in the lower organic insulating film 12 and the inorganic insulating film 13, without over-etching the lower organic insulating film 12 excessively.

In the embodiment described above, the etching gas used in the dry etching steps of FIGS. 4 and 5 contains both oxygen gas (O₂) and nitrogen gas (N₂). Nonetheless, etching gas containing at least one of O₂ gas and N₂ gas may be used.

Additional advantages and modifications will readily occur to those skilled in the art. Therefore, the invention in its broader aspects is not limited to the specific details and representative embodiments shown and described herein. Accordingly, various modifications may be made without departing from the sprint or scope of the general inventive concept as defined by the appended claims and their equivalents.

What is claimed is:

1. A method of manufacturing a semiconductor device, comprising:
forming a lower organic insulating film on an underlying region;
forming an inorganic insulating film on the lower organic insulating film;
forming an upper organic insulating film on the inorganic insulating film;
making a first hole which has first and second parts passing through the upper organic insulating film and the inorganic insulating film, respectively; and
performing dry etching on the upper organic insulating film and that part of the lower organic insulating film which lies below the first hole, by using etching gas containing at least one of oxygen gas and nitrogen gas, thereby making a second hole having the second part and a third part which passes through the lower organic insulating film, and thereby removing the upper organic insulating film,
wherein performing the dry etching includes removing at least a part of the upper organic insulating film in a condition that residence time of the etching gas is 0.25 second or more in a chamber in which the dry etching is performed.

2. The method according to claim 1, wherein the upper organic insulating film is formed thicker than the lower organic insulating film.

3. The method according to claim 1, wherein the lower and upper organic insulating films are formed of first and second organic insulating films, respectively, and the first organic insulating film is etched with the etching gas at a higher etching rate than the second organic insulating film is etched with the etching gas if the first and second organic insulating films are formed on flat surfaces.

4. The method according to claim 1, wherein the second hole has an aspect ratio of 3 at least.

5. The method according to claim 1, wherein the upper organic insulating film is removed in whole before the underlying region is exposed through the third part, in the dry etching.

6. The method according to claim 1, wherein the upper organic insulating film contains carbon as main component.

7. The method according to claim 1, wherein the lower organic insulating film has a relative dielectric constant of 3.3 at most.

8. The method according to claim 1, wherein the lower organic insulating film has a lower relative dielectric constant than the upper organic insulating film.

9. The method according to claim 1, wherein the lower organic insulating film is a porous organic insulating film.

10. The method according to claim 1, wherein the lower organic insulating film has a lower density than the upper organic insulating film.

11. The method according to claim 1, wherein the lower organic insulating film is used as an interlayer insulating film.

12. The method according to claim 1, wherein the inorganic insulating film is formed of a silicon oxide film.

13. The method according to claim 1, wherein the etching gas contains oxygen gas and nitrogen gas.

14. The method according to claim 1, wherein the residence time T (seconds) is given as follows:
T=(V×P)/(1.27×10⁻²×F)
where V (liter) is the volume of the chamber, P (Torr) is the pressure in the chamber, and F (sccm) is the flow rate of the etching gas.

15. The method according to claim 1, wherein the upper organic insulating film is etched at a higher etching rate than the lower organic insulating film, in removing said at least a part of the upper organic insulating film in the condition that the residence time of the etching gas is 0.25 second or more.

16. The method according to claim 1, wherein an entire side surface of the second hole is substantially vertical.

17. The method according to claim 1, further comprising forming an SOG film on the upper organic insulating film and etching the SOG film, wherein the SOG film after the etching is used as mask for making the first part of the first hole.

18. The method according to claim 17, wherein the SOG film is removed before the second part of the first hole passes through the inorganic insulating film, in making the second part of the first hole.

19. The method according to claim 18, wherein the upper organic insulating film is used as mask after the SOG film is removed, in making the second part of the first hole.

20. The method according to claim 1, further comprising filling the second hole with conductive material.
